(19) United States
(12) Patent Application Publication
(10) Pub. No.: US 2026/0066880 A1
(43) Pub. Date: Mar. 5, 2026

(54) TIME DELAY UNIT FOR HIGH FREQUENCY APPLICATIONS

(71) Applicant: Qorvo US, Inc., Greensboro, NC (US)

(72) Inventor: Charles Forrest Campbell, Dallas, TX (US)

(21) Appl. No.: 19/297,552

(22) Filed: Aug. 12, 2025

Related U.S. Application Data
(60) Provisional application No. 63/688,772, filed on Aug. 29, 2024.

(51) Int. Cl. H03H 11/26

(52) U.S. Cl. CPC H03H 11/265

(57) ABSTRACT

A time delay circuit includes a first port, a second port, a reference path coupled between the first and second ports, a delay path coupled between the first and second ports, and a control circuit configured to activate one of the reference path and the delay path. The reference path includes a series transistor and a first inductor connected in parallel with the series transistor. The delay path includes a first shunt transistor, a second inductor connected in parallel with the first shunt transistor, and a first impedance inverter coupled between the first port and the first shunt transistor.

### RELATED PATENT APPLICATION(S)

The present application claims the benefit of U.S. Provisional Application No. 63/688,772, entitled “TIME DELAY UNIT FOR HIGH FREQUENCY APPLICATIONS” and filed on Aug. 29, 2024, which is hereby incorporated by reference in its entirety.

### FIELD OF THE DISCLOSURE

The technology disclosed herein relates generally to time delay circuits, and more particularly to single-bit and multi-bit time delay units (TDUs) based on shunt and series transistors for high frequency applications.

### BACKGROUND

Variable time delay circuits, particularly those n-bit time delay units (TDUs) employing digital control mechanisms, are critical components in modern phased array antennas and radar systems. These circuits are important for various applications, where precise control over signal timing is necessary to ensure optimal system performance. The ability to introduce controlled delays into radio frequency (RF) signals allows for the enhancement of several key functionalities within these systems.

Taking phase array antennas as an example, one reason for integrating TDUs is to minimize “beam squint.” Beam squint is a phenomenon that occurs when the beam direction of an antenna array changes with frequency, leading to a misalignment between the intended and actual beam direction. By using TDUs to finetune time delays, systems can maintain consistent beam direction across a broad frequency range, thereby reducing beam squint and enhancing the accuracy and effectiveness of the phased array antennas. In addition to mitigating beam squint, TDUs are essential for spatial alignment within phased array antennas. Phased array antennas consist of multiple radiating elements that are physically separated from one another. To ensure that the signals from each element combine coherently in the desired direction, time delays must be introduced to compensate for the physical separation between the radiating elements. By adjusting the timing of the signals, the array can achieve proper spatial alignment, which is critical for maximizing signal strength in the desired direction and minimizing interference from other directions. TDUs also play a significant role in pulse compression radar systems. Pulse compression radar involves transmitting a long-duration pulse that is modulated with a specific waveform, such as a linear frequency modulation. Upon receiving the reflected signal, the radar system compresses the pulse in time to achieve high range resolution. Accurate time delay circuits are critical to align and process these pulses effectively, ensuring that the system can detect and resolve targets at varying distances with high precision.

Overall, the integration of TDUs into RF and microwave systems is essential for achieving high performance in applications ranging from beam steering in phased arrays to precise target detection in radar systems. These circuits provide the necessary control over signal timing to compensate for various physical and system-related factors, thereby enhancing the overall functionality and accuracy of advanced communication and sensing technologies. As the demand for high-frequency applications continues to grow, the design and implementation of TDUs are evolving to meet increasingly stringent performance requirements. Addressing challenges related to key performance parameters such as insertion loss, isolation, and circuit form factors is crucial to ensuring the efficient operation and integration of TDUs in advanced RF and microwave systems.

### SUMMARY

Example aspects of the present disclosure offer innovative solutions for the development of single-bit and multi-bit time delay units (TDUs) designed for high frequency applications. The exemplary TDU architecture leverages shunt transistors, coupled with impedance inverters, to manage the selection between reference and delay paths. Embodiments illustrated in FIGS. 3 and 4 utilize shunt transistors (Q1) in a delay path and a series transistor (Q2) in a reference path. This configuration avoids series FETs in the low loss settings in a delay path, which are resistive and lossy in the “ON” state. Instead, when the shunt transistors (Q1) in the delay path are turned “OFF” they look like very low loss capacitors which can be resonated with a Coff resonator. This approach, which eliminates the need for series transistors in the delay path, significantly enhances the insertion loss performance of the corresponding bit of the TDU. When set to the reference path, the loss of the series transistor (Q2) in the reference path is used to help equalize the insertion loss of the delay path, such that both paths have approximately equal loss. The balance of the insertion loss can be further tuned by adjusting the size of the transistor in the reference path, as the smaller the transistor the greater the loss, and vice versa. Additionally, the proposed TDU architecture supports monolithic integration, a critical feature that allows the integration of amplifiers, mixers, and detectors within a single monolithic microwave integrated circuit (MMIC), which minimizes signal losses and thereby optimizes overall system performance for RF and microwave systems.

In an exemplary embodiment, a time delay circuit includes a first port, a second port, a reference path coupled between the first and second ports, a delay path coupled between the first and second ports, and a control circuit configured to activate one of the reference path and the delay path. The reference path includes a series transistor and a first inductor connected in parallel with the series transistor. The delay path includes a first shunt transistor, a second inductor connected in parallel with the first shunt transistor, and a first impedance inverter coupled between the first port and the first shunt transistor. In some instances, the delay path further includes a second shunt transistor, a third inductor connected in parallel with the second shunt transistor, and a second impedance inverter coupled between the second port and the second shunt transistor. In some instances, the delay path further includes a delay adjuster line coupled between the first impedance inverter and the second impedance inverter. In some instances, the first impedance inverter is in a form of a quarter wavelength transmission line. In some instances, the reference path further includes a first DC blocking capacitor coupled between the first port and the series transistor and a second DC blocking capacitor coupled between the second port and the series transistor. In some instances, the reference path further includes a first reference adjuster line coupled between the first port and the series transistor and a second reference adjuster line coupled between the second port and the series transistor. In some instances, the reference path further includes a first shunt transmission line and a second shunt transmission line, and wherein the series transistor is coupled between the first shunt transmission line and the second shunt transmission line. In some instances, the first inductor is in a form of a transmission line. In some instances, the second inductor is in a form of a transmission line. In some instances, the first inductor is configured to resonant with an off-state capacitance of the series transistor, and the second inductor is configured to resonant with an off-state capacitance of the first shunt transistor. In some instances, the reference path further includes a first capacitor connected in parallel with the series transistor, and the delay path further includes a second capacitor connected in parallel with the first shunt transistor. In some instances, the control circuit is configured to apply a first control voltage to a gate of the series transistor and a second control voltage to a gate of the first shunt transistor, and the first control voltage and the second control voltage have a same value. In some instances, in an operating band of the time delay circuit, an insertion loss of the time delay circuit at a higher frequency is less than at a lower frequency. In some instances, the series transistor and the first shunt transistor have different sizes.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description, serve to explain the principles of the disclosure.

FIGS. 1A and 1B illustrate block diagrams of a single-bit TDU and a multi-bit TDU, respectively, according to some aspects of the present disclosure.

FIG. 2 illustrates a circuit diagram of a single-bit TDU based on a shunt-only switch architecture, according to some aspects of the present disclosure.

FIG. 3 illustrates a circuit diagram of a single-bit TDU with a delay path based on a shunt-only switch architecture, according to some aspects of the present disclosure.

FIG. 4 illustrates an alternative circuit diagram of a single-bit TDU with a delay path based on a shunt-only switch architecture, according to some aspects of the present disclosure.

FIGS. 5A, 5B, and 5C illustrate circuit layouts of 32 ps, 16 ps, and 8 ps TDUs, respectively, according to some aspects of the present disclosure.

FIGS. 6A, 6B, 7A, 7B, 8A, and 8B illustrate simulated performance characteristics of the TDUs in FIGS. 5A-C, respectively, according to some aspects of the present disclosure.

FIG. 9 illustrates a circuit layout of a multi-bit TDU by cascading the single-bit TDUs in FIGS. 5A-C, according to some aspects of the present disclosure.

FIGS. 10A and 10B illustrate simulated performance characteristics of the multi-bit TDU in FIG. 9, according to some aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The integration of variable time delay circuits into radio frequency (RF) and microwave systems is a critical factor in achieving high performance across a range of applications, from precise beam steering in phased arrays to accurate target detection in radar systems. These circuits provide the necessary control over signal timing, enabling systems to compensate for physical and system-related variables, thereby enhancing the overall functionality and accuracy of advanced communication and sensing technologies. As the demand for high-frequency applications continues to grow, the design and implementation of single-bit and multi-bit time delay units (TDUs) are evolving to meet increasingly stringent performance requirements. This evolution includes addressing challenges related to key performance parameters such as insertion loss, isolation, and circuit form factors. Overcoming these challenges is essential to ensuring the efficient operation and seamless integration of TDUs in cutting-edge RF and microwave systems. In traditional designs, TDUs often incorporate series transistors as switches within both the reference and delay paths. While this approach is widely used, it tends to increase insertion loss due to on-state resistance of the series transistors, which can degrade the signal quality and efficiency of the system, particularly in high frequency applications.

The present disclosure introduces innovative approaches for creating single-bit and multi-bit TDUs tailored for high frequency applications. The proposed TDU architecture utilizes shunt transistors in conjunction with impedance inverters to efficiently switch RF signal between the routing of signals into either a reference path or a delay path of the TDU circuit. By avoiding the use of series transistors in the delay path, this architecture substantially improves the insertion loss performance of the TDU, making it more suitable for advanced RF and microwave systems.

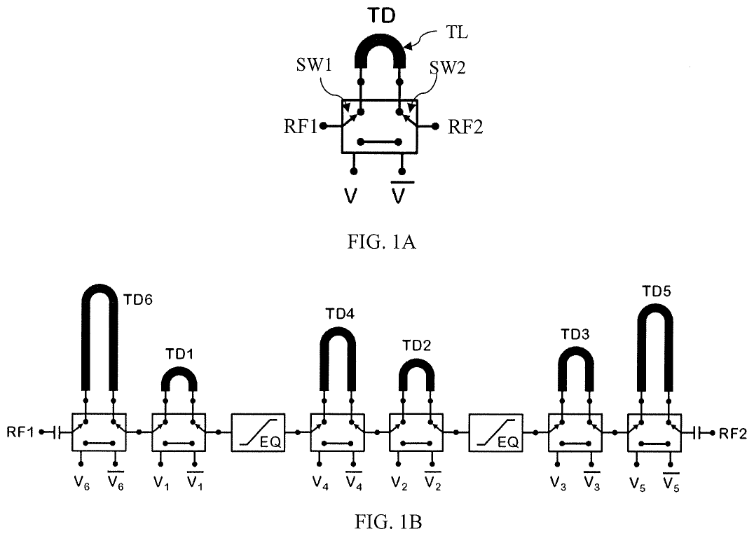

Before addressing exemplary aspects of the present disclosure, a brief discussion of a conventional approach to single-bit and multi-bit TDUs and their limitations is provided with reference to FIGS. 1A and 1B.

FIG. 1A illustrates a block diagram of a single-bit switched line TDU, which serves as a fundamental building block for multi-bit TDU designs. This circuit uses a pair of single-pole double-throw (SPDT) switches (denoted as SW1 and SW2 in the figure) to toggle between two distinct signal paths: a short reference path and a longer delay path. The reference path represents a direct connection with minimal delay between the input port and output port (denoted as RF1 and RF2 in the figure, respectively), while the delay path introduces a specific time delay through an extended transmission line (denoted as TL in the figure), typically realized with a 50-ohm (50Ω) impedance microstrip line, strip line, coplanar waveguide, or other transmission line in a suitable form.

The primary function of the single-bit TDU is to provide a selectable time delay to an RF signal by switching between these two paths. The difference in length between the reference path and the delay path corresponds to the delay time introduced by the circuit. This difference, often referred to as the “time delay” (TD) of the bit, is critical in applications where precise timing control of signals is required, such as in phased array antennas and radar systems.

Control voltages, usually a pair of complementary voltages (denoted as V and V in the figure) are applied to the SPDT switches to determine whether the signal should pass through the reference path or the delay path. These control voltages are essential for the operation of the switches, allowing for dynamic selection of the desired delay. Direct current (DC) blocks may also be included to prevent DC bias from interfering with the RF signal path.

FIG. 1B presents a block diagram of a multi-bit TDU, particularly a 6-bit switch line TDU, which is constructed by cascading six instances of the single-bit TDU described in FIG. 1A. Each of the six TDUs (TD1 through TD6) is realized using an extended transmission line, similar to the single-bit design. In the depicted embodiment, the time delays may be realized using 50-ohm microstrip lines. These microstrip lines may be fabricated on a printed circuit board (PCB) or within a monolithic microwave integrated circuit (MMIC). The 50-ohm impedance is a standard value chosen to ensure maximum power transfer and minimal signal reflection at interfaces. The length of each microstrip line determines the amount of delay introduced; longer lines correspond to longer delays. In this 6-bit design, six distinct delay lines are used, offering a range of delay values that can be combined to achieve a desired overall delay.

In the multi-bit TDU, each stage contributes a different amount of delay, and the overall delay can be adjusted by selectively activating the appropriate combination of bits. For example, the control voltages V1 through V6 and respective complimentary voltages are applied to the corresponding SPDT switches to determine whether each stage's delay path or reference path is used. The delay introduced by each stage (or referred to as bit) is cumulative, allowing for a wide range of delay values to be selected by the user. By controlling these voltages, the switching mechanism configures the total delay dynamically. The combined configuration provides greater flexibility and a wider range of selectable time delays, making it suitable for more complex RF and microwave applications.

Furthermore, as depicted in FIG. 1B, equalization circuitry (denoted as EQ in the figure) may be integrated into stages of a multi-bit TDU to flatten the frequency response. The purpose of equalization is to compensate for frequency-dependent variations in insertion loss or delay that occur within the delay lines or switches. This ensures that the TDU provide a consistent delay and signal amplitude across its entire operating bandwidth. The design may also include DC blocks, such as the series capacitors at the RF1 and RF2 nodes, and other passive components to further optimize performance and prevent unwanted DC bias from affecting the RF signal path. Additionally, DC blocks are employed to prevent DC bias from passing through the RF signal path, which could otherwise affect the operation of the RF components.

The bandwidth requirement of the TDUs is a key factor in determining the switch topology, the delay medium, and the need for equalization. Wideband designs, typically defined as those with a bandwidth exceeding 50%, require wideband switch topologies that can maintain consistent performance across a broad frequency range. Series-shunt switch architecture is often employed in wideband designs. For example, the circuit depicted in FIGS. 1A and 1B uses a series-shunt switch architecture, which includes both series and shunt field-effect transistors (FETs) in the switching network. In this architecture, series FETs are used to pass the signal through the delay line when in the on-state, and shunt FETs are used to isolate the delay line when it is not selected. However, this architecture introduces a significant amount of insertion loss due to the non-zero on-state resistance of the series switch FETs. In the example 6-bit TDU, there are twelve series switch FETs, each contributing to the overall insertion loss. This can be problematic, especially at higher frequencies such as the Ka-band (e.g., from 26.5 to 40 GHz), where even small resistances can result in substantial signal loss.

At Ka-band frequencies, insertion loss of the TDUs becomes more pronounced. Delay line losses also increase as the delay line length is not frequency dependent, which means as frequency increases the physical length of the delay line becomes more significantly relative to the wavelength and leads to higher losses. The series-shunt switch architecture, while useful at lower frequencies, was found to have too much loss at Ka-band due to the combined effects of the series FET resistances and the delay line losses.

Meanwhile, for applications with a narrower operating bandwidth, shunt-only switch architecture may be considered as an alternative to series-shunt switch architecture. In a shunt-only switch architecture, when the delay path is selected the signal is passed directly without passing through a series FET. This can reduce the overall insertion loss because the delay path does not encounter the resistance of a series FET.

Furthermore, in some embodiments, shunt-only switch architecture may simplify control circuitry with a need for only a single control voltage for each bit of the TDU. As a comparison, the series-shunt switch architecture typically requires complementary control voltages to operate. This means that for each bit of the TDU with a series-shunt switch architecture, a pair of complementary control voltages are needed. This requires a more complex control circuit, which can introduce additional design challenges for control signal routing with a limited layout area.

Thus, for some high frequency applications with lessened requirement on operating bandwidths, delay paths adopting a simpler shunt-only switch architecture may be sufficient and can offer lower insertion loss and simpler control circuitry.

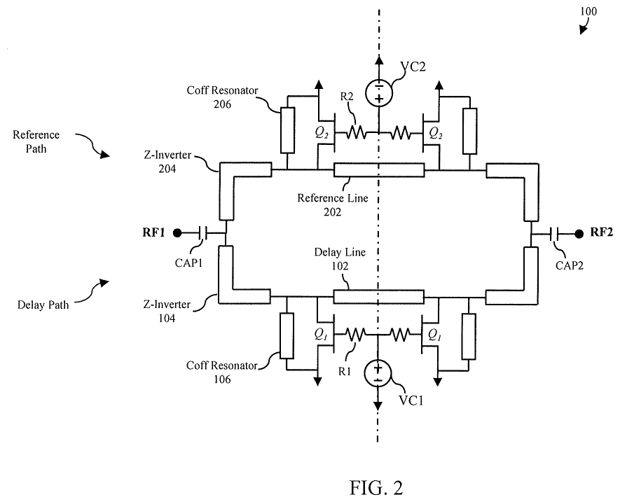

Reference is made to FIG. 2, which depicts a diagram of a circuit 100 of a single-bit TDU based on the shunt-only switch architecture. The circuit 100 includes a reference path and a delay path. The delay path, located in the lower part of the depicted circuit diagram, includes a transmission line 102 as a delay line, shunt switches Q1, impedance inverters (or Z-inverters) 104, and Coff resonators 106. The reference path, located in the upper part of the depicted circuit diagram, includes a transmission line 202 as a reference line, shunt switches (Q2), impedance inverters (or Z-inverters) 204, and Coff resonators 206. In circuit implementation, each of the impedance inverters 104, 204, and Coff resonators 106, 206 may be in the form of a transmission line, and each of the shunt switches Q1, Q2 may be in the form of a field effect transistor (FET).

The circuit 100 routes RF signals from the input port RF1 to the output port RF2 through either the reference path or the delay path based on the states of the transistors Q1 and Q2, which are controlled by the control voltages VC1 and VC2, respectively. The circuit 100 also incorporates capacitors CAP1 and CAP2, which serve as DC blocks. These capacitors are placed at the input port RF1 and output port RF2 points to prevent DC bias from entering or leaving the circuit. The DC blocking helps maintaining the integrity of RF signals and protecting the sensitive RF components within the circuit. The circuit 100 also incorporates resistors R1 and R2, which are gate series resistors connected to the gates of transistors Q1 and Q2, respectively. These resistors help stabilizing the operation of the transistors by limiting the gate current and reducing the possibility of oscillations.

Since the circuit 100 depicted in the figure consists of two identical half portions connected in series (as separated by the imaginary dash line in the figure), it is helpful to analyze one half of the circuit first and then extend that understanding to the whole circuit.

In operation, the selection between the reference and delay paths is controlled by the biasing of the shunt transistors Q1, Q2. For the reference path to be active, transistor Q1 in the delay path is turned on (on-state) by applying a control voltage VC1 as HIGH. The transistor Q1 in the on-state turns on its channel and shunts the output of the impedance inverter 104 in the delay path to ground. In some embodiments, the impedance inverter 104 is a quarter-wavelength (λ/4) transmission line. When an RF signal travels through a transmission line that is one-quarter of the signal's wavelength long, the impedance at one end of the line is transformed to its inverse at the other end. This action forces the input of the impedance inverter 104 in the delay path to present a high impedance, effectively preventing the RF signal from entering the delay path. Concurrently, transistor Q2 in the reference path is turned off (off-state) by applying a control voltage VC2 at LOW. The transistor Q2 in the off-state turns off its channel and behaves as a capacitor. The Coff resonator 206, acting as an inductor in shunt with the transistor Q2, resonates with the off-state capacitance of the transistor Q2 at the operating frequency, creating an effective open circuit. This configuration allows the signal to pass through the impedance inverter 204 and the reference line 202 as if through one continuous 50-ohm transmission line without “seeing” the transistor Q2 and the Coff resonator 206.

On the other hand, for the delay path to be active, the control voltage VC1 is set to LOW, turning off the transistor Q1 (off-state), and the Coff resonator 106 in the delay path resonates with the off-state capacitance of the transistor Q1 at the operating frequency, creating an effective open circuit. This allows the signal to travel through the impedance inverter 104 and the delay line 102 as if through one continuous 50-ohm transmission line without “seeing” the transistor Q1 and the Coff resonator 106. Simultaneously, transistor Q2 in the reference path is turned on (on-state) by applying the control voltage VC2 as HIGH, shunting the output of the impedance inverter 204 in the reference path to ground. This action causes the input of the impedance inverter 204 in the reference path to present a high impedance, effectively preventing the RF signal from taking the reference path.

The second half of the circuit 100 operates in the same manner as the first half, further routing the signal from the middle point of the circuit to the output port (RF2) either through a second half of the reference path or a second half of the delay path, depending on the control voltages applied to the corresponding shunt transistors Q1 and Q2. If the transistors Q1 and Q2 are complementary metal-oxide-semiconductor (CMOS) transistors, the control voltage of HIGH to turn on the transistors may be a positive voltage (such as 4V), and the control voltage of LOW to turn off the transistors may be sufficiently lower than the pinch-off voltage (such as 0V). If the transistors Q1 and Q2 are gallium nitride (GaN) transistors, the control voltage of HIGH to turn on the transistors may be a voltage around the ground potential (such as 0V), and the control voltage of LOW to turn off the transistors may be sufficiently lower than the pinch-off voltage (such as −4V).

In the circuit 100, when the delay path is selected, the transistors Q1 are in the off-state and there is no series transistor in the delay path. In other words, there is nearly no loss introduced by the switches in the delay path. Compared with the series-shunt switch architecture discussed above that includes series switches in the delay path, the shunt-only switch architecture leverages the benefits of shunt transistors, impedance inverters, and Coff resonators to achieve reliable and adjustable time delays with a low insertion loss.

Notably, a TDU based on the shunt-only switch architecture is particularly well-suited for applications that require a bandwidth of 50% or less. This is primarily because the architecture relying on accuracy of the quarter-wavelength impedance inverters and Coff resonators, which are most effective in narrowband scenarios. The quarter-wavelength impedance inverters function by transforming the impedance seen at one end of the line to its inverse at the other end, which relies heavily on the precise tuning of the line length to a quarter of the signal's wavelength. Similarly, Coff resonators are designed to resonate at a specific operating frequency, creating an open circuit condition that effectively isolates parts of the circuit when the shunt switch is in the off-state. However, the accuracy and effectiveness of both the impedance inverters and Coff resonators reduce as the bandwidth increases, because they are optimized for a narrow frequency range. In applications with wider bandwidths, the variations in signal frequency can lead to less accurate impedance transformations and resonance conditions, which can degrade the overall performance of the TDU. Therefore, shunt-only switch architecture is more reliable and efficient in systems where the operational bandwidth does not exceed 50%, ensuring that the impedance inversion and resonance mechanisms function as intended. For example, some applications operating at Ka-band utilize a band from 32 GHz to 38 GHz, which would be suitable to adopt such TDUs.

Still referring to FIG. 2, in the circuit 100, the delay introduced by the TDU is primarily the result of the difference in signal propagation time between the delay line 102 and the reference line 202. While these transmission lines are designed to introduce different delays, the quarter-wavelength impedance inverters 104 and 204 occupy a significant amount of the chip real estate. However, despite their large footprint, these impedance inverters do not contribute to the differential time delay provided by the TDU. The delay time introduced by the impedance inverters is consistent for both the delay path and the reference path, meaning that they do not enhance the relative delay difference between these two paths. Consequently, a substantial portion of the circuit's layout is dedicated to accommodating these impedance inverters, which, while essential for proper circuit function, do not directly impact the amount of time delay (TD) that the TDU is designed to provide. This results in an inefficient use of a chip's area.

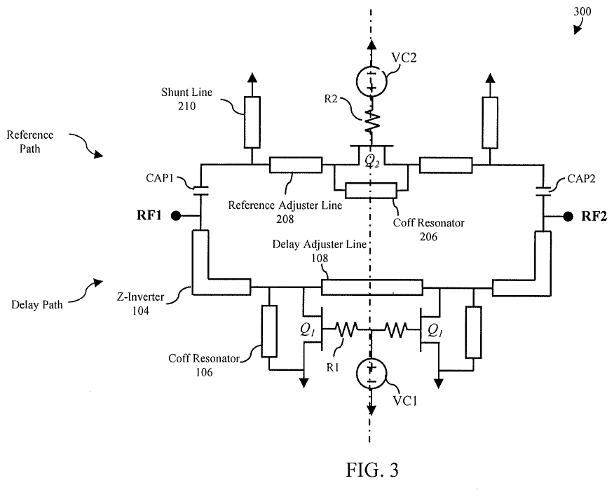

Reference is made to FIG. 3, which depicts a diagram of a circuit 300 of a single-bit TDU. Similar to the circuit 100 as depicted in FIG. 2, the circuit 300 includes a reference path and a delay path. The delay path, located in the lower part of the depicted circuit diagram, includes shunt switches Q1, impedance inverters (or Z-inverters) 104, Coff resonators 106, and a transmission line 108 as a delay adjuster line. The delay adjuster line 108 finetunes the total time delay introduced by the delay path. The reference path, located in the upper part of the depicted circuit diagram, does not have shunt switches but a series switch Q2. The series switch Q2 functions as a single-pole single-throw (SPST) switch in the reference path. The reference path also includes Coff resonator 206, transmission lines 208 as reference adjuster lines, shunt lines 210, and capacitors CAP1 and CAP2. The reference adjuster lines 208 finetunes the total time delay introduced by the reference path. The shunt lines 210 provide a bias to the ground (GND). The shunt lines 210 help tuning the return loss and the delay flatness in the passband. The capacitors CAP1 and CAP2, now positioned in the reference path, help raising impedance at the nodes of the input port RF1 and the output port RF2, respectively, when the reference path is inactive. In circuit implementation, each of the impedance inverters 104, the Coff resonators 106, 206, the delay adjuster lines 108, 208, and the shunt lines 210 may be in the form of a transmission line, and each of the switches Q1, Q2 may be in the form of a field effect transistor (FET).

The circuit 300 routes RF signals from the input port RF1 to the output port RF2 through either the reference path or the delay path based on the states of the transistors Q1 and Q2, which are controlled by the control voltages VC1 and VC2, respectively. The circuit 300 may optionally incorporate capacitors (not depicted in FIG. 3) other than CAP1 and CAP2 in the main signal path before splitting as DC blocks for the whole TDU. The circuit 300 also incorporates resistors R1 and R2, which are gate series resistors connected to the gates of transistors Q1 and Q2, respectively. These resistors help stabilizing the operation of the transistors by providing a high impedance to the gate connection such that the bias circuitry is isolated and does not impact the TDU operation.

Since the circuit 300 depicted in the figure consists of two identical half portions connected in series (as separated by the imaginary dash line in the figure), it is helpful to analyze one half of the circuit first and then extend that understanding to the whole circuit.

In operation, the selection between the reference and delay paths is controlled by the biasing of the transistors Q1, Q2. For the reference path to be active, the shunt transistor Q1 in the delay path is turned on (on-state) by applying a control voltage VC1 as HIGH. The shunt transistor Q1 in the on-state turns on its channel and shunts the output of the impedance inverter 104 in the delay path to ground. In some embodiments, the impedance inverter 104 is a quarter-wavelength (λ/4) transmission line. When an RF signal travels through a transmission line that is one-quarter of the signal's wavelength long, the impedance at one end of the line is transformed to its inverse at the other end. This action forces the input of the impedance inverter 104 in the delay path to present a high impedance, effectively preventing the RF signal from entering the delay path. Concurrently, the series transistor Q2 in the reference path is also turned on (on-state) by applying a control voltage VC2 at HIGH. The series transistor Q2 in the on-state turns on its channel and equivalently functions as a short in the reference path. This configuration allows the signal to pass through the reference adjuster line 208 and the channel of the series transistor Q2 without “seeing” the Coff resonator 206.

On the other hand, for the delay path to be active, the control voltage VC1 is set to LOW, turning off the transistor Q1 (off-state). The transistor Q1 in the off-state turns off its channel and behaves as a capacitor. The Coff resonator 106, acting as an inductor in shunt with the transistor Q1, resonates with the off-state capacitance of the transistor Q1 at the operating frequency, creating an effective open circuit. This allows the signal to travel through the impedance inverter 104 and the delay adjuster line 108 as if through one continuous 50-ohm transmission line without “seeing” the transistor Q1 and the Coff resonator 106. Simultaneously, transistor Q2 in the reference path is turned off (off-state) as well by applying the control voltage VC2 as LOW. The transistor Q2 in the off-state turns off its channel and behaves as a capacitor. The Coff resonator 206, acting as an inductor in shunt with the transistor Q2, resonates with the off-state capacitance of the transistor Q2 at the operating frequency, creating an effective open circuit that blocks the reference path.

The second half of the circuit 300 operates in the same manner as the first half, further routing the signal from the middle point of the circuit to the output port (RF2) either through a second half of the reference path or a second half of the delay path, depending on the control voltages applied to the corresponding transistors Q1 and Q2. If the transistors Q1 and Q2 are complementary metal-oxide-semiconductor (CMOS) transistors, the control voltage of HIGH to turn on the transistors may be a positive voltage (such as 4V), and the control voltage of LOW to turn off the transistors may be sufficiently lower than the pinch-off voltage (such as 0V). If the transistors Q1 and Q2 are gallium arsenide (GaAs) transistors, the control voltage of HIGH to turn on the transistors may be a voltage around the ground potential (such as 0V), and the control voltage of LOW to turn off the transistors may be sufficiently lower than the pinch-off voltage (such as −4V). Similarly, in various other embodiments, the transistors Q1 and Q2 may be based on gallium nitride (GaN), SOI, InP, PCM, MEMs, or other suitable configurations, with suitable control voltage settings.

Notably, compared with the circuit 100 depicted in FIG. 2, the circuit 300 does not have impedance inverters in the reference path. Therefore, the impedance inverters 104 in the delay path also contributes to the differential time delay provided by the TDU. The time delay introduced by the TDU is the difference between the time for signal to pass through two impedance inverters 104 and one delay adjuster line 108 in the delay path and the time for signal to pass through two reference adjuster lines 208 and a channel of the series transistor Q2 in the reference path. Thus, the length of the delay adjuster line 108 can be significantly reduced with the aid from the impedance inverters 104. The length of the reference adjuster lines 208 is for finetuning the differential time delay. As a result, the chip area of the TDU is better utilized.

Accordingly, the circuit 300 integrates the benefits of both the series-shunt switch architecture and the shunt-only switch architecture. When the delay path is selected, the transistors Q1 are in the off-state and there is no series switch in the delay path, and thus no loss introduced by the switches in the delay path. Meanwhile without having the impedance inverters in the reference path but a series transistor Q2 acting as an SPST switch, the circuit area is significantly reduced. Further, the transistors Q1 and Q2 may have different sizes. Particularly, the size of the transistor Q2 acting as an SPST switch may be separately optimized to balance time delay and insertion loss in the reference path.

Furthermore, compared with the circuit 100 depicted in FIG. 2, the circuit 300 have the same control voltage value for VC1 and VC2. That is, the VC1 and VC2 are either both HIGH to select the reference path, or both LOW to select the delay path. The control circuitry for the TDU is simplified without a need for generating a pair of complimentary control voltages, which also saves valuable chip area.

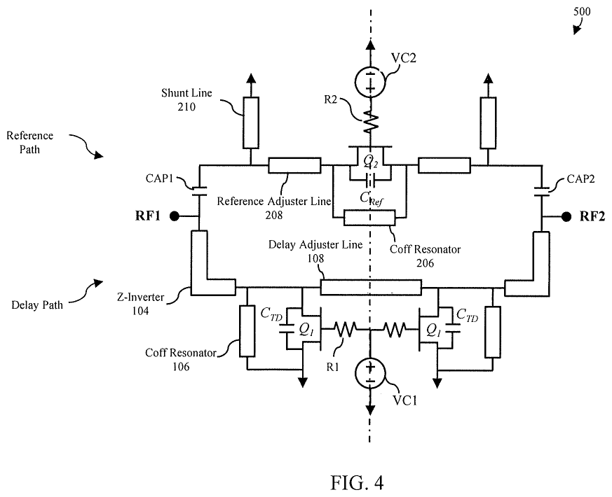

Reference is made to FIG. 4, which depicts a diagram of a circuit 500 of a single-bit TDU. Many aspects of the circuit 500 is similar to the circuit 300 depicted above. One difference is that the circuit 500 includes capacitors CTD to shunt with the transistors Q1 and a capacitor C_{Ref} to shunt with the transistor Q2. The capacitors CTD and C_{Ref} are introduced to address the sensitivity of the circuit to variations in the off-state capacitance of the transistors Q1 and Q2. Initially, the circuit may be optimized based on nominal values of the on-state resistance and off-state capacitance of the transistors. Yet deviations from these nominal values may cause the circuit's performance to degrade, particularly for TDU providing relatively larger time delay (e.g., 32 ps at 32-38 GHz). To mitigate this issue, a fixed capacitor is added in parallel with a transistor's off-state capacitance. The addition of this fixed capacitor works by altering the resonant condition. Specifically, the Coff resonator 106 or 206 now resonate with the combined capacitance of the respective transistor's off-state capacitance and the fixed capacitor. Although this configuration resonates with a slightly larger capacitance, it still falls within the acceptable bandwidth limits of the design. The key advantage of this approach is that a portion of the total capacitance is now fixed, reducing the circuit's sensitivity to variations in the transistor's off-state capacitance. As a result, even if the transistor's capacitance deviates from its nominal value, the impact on the circuit's overall performance is lessened because the fixed capacitor stabilizes a significant portion of the total capacitance. This adjustment leads to improved consistency and reliability in the circuit's time delay performance.

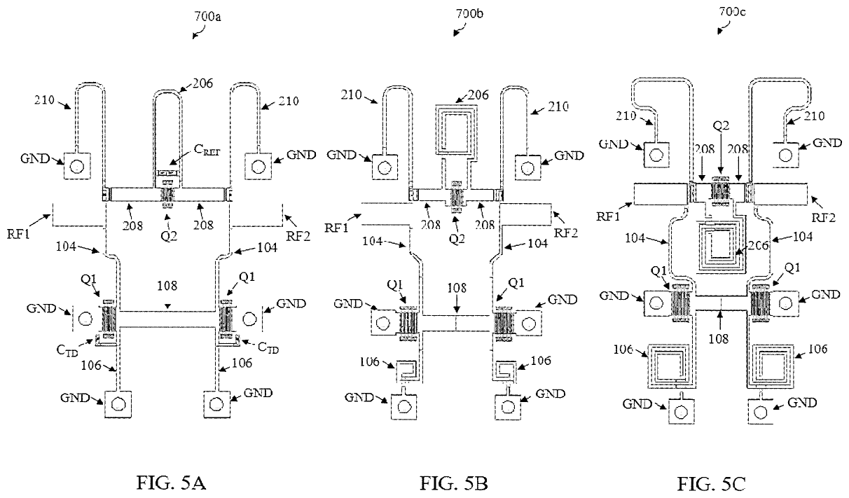

FIGS. 5A, 5B, 5C illustrate a circuit layout 700a corresponding to a single-bit 32 ps TDU, a circuit layout 700b corresponding to a single-bit 16 ps TDU, and a circuit layout 700c corresponding to a single-bit 8 ps TDU, respectively. Each TDU is designed for operating in a band of 32-38 GHz. Since the TDU with a larger time delay (e.g., 32 ps) is easier to be impacted by the deviation of the off-state capacitance, the circuit layout 700a is based on the circuit diagram 500 depicted in FIG. 4 with the fixed capacitors CTD and C_{Ref}, while the circuit layouts 700b and 700c are based on the circuit diagram 300 depicted in FIG. 3 without extra fixed capacitors. As shown in the circuit layouts 700a-c, the transmission lines may be optimized for each TDU. For example, the impedance inverter 104 may be thinner than a standard 50-ohm transmission line to bring in more inductance for better return loss performance; the Coff resonators 106 may be a straight line in circuit layout 700a or a spiral inductor in circuit layouts 700b-c; the Coff resonator 206 may be a U-shaped line in circuit layout 700a or a spiral inductor in circuit layouts 700b-c; and the transistors Q1 and Q2 may have different sizes in the circuit layouts 700a-c.

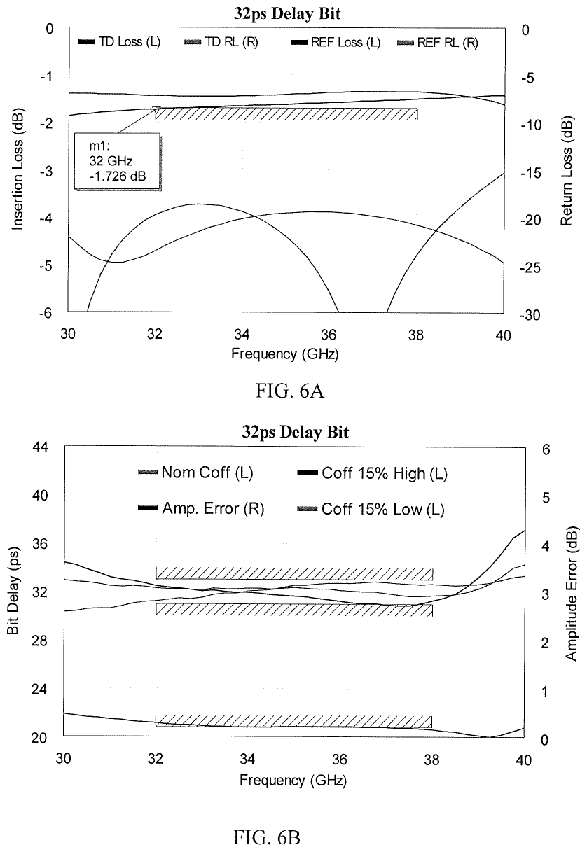

FIGS. 6A and 6B illustrate the performance characteristics of the 32 ps TDU with the circuit layout 700a. FIG. 6A displays both the insertion loss and return loss across a frequency range of 30 to 40 GHz. The insertion loss curves show the signal loss as it passes through the delay path (TD Loss) and the reference path (REF Loss). At 32 GHz, the insertion loss for the reference path is approximately 1.726 dB, and the insertion loss for the delay path is a quarter dB less, demonstrating efficient performance with minimal signal degradation. The return loss curves represent the amount of signal reflected back towards the source, with the delay path (TD RL) and the reference path (REF RL) maintaining low reflections. FIG. 6B focuses on the delay and amplitude error across the same frequency range. The plot shows three curves representing the bit delay (in picoseconds) for different conditions: nominal off-state capacitance, a 15% higher capacitance, and a 15% lower capacitance. The bit delay remains relatively stable across the frequency band, with variations within acceptable limits, even when accounting for a 15% variation in off-state capacitance. Additionally, the amplitude error curve shows the amplitude error, which remains low, indicating that the system maintains consistent signal amplitude regardless of the selection of a delay path or a reference path. Notably, the insertion loss curve has a tendency to go uphill (less insertion loss) with the frequency goes higher, indicating there is no need for an extra equalization circuit (as shown in FIG. 1B) to compensate the frequency response.

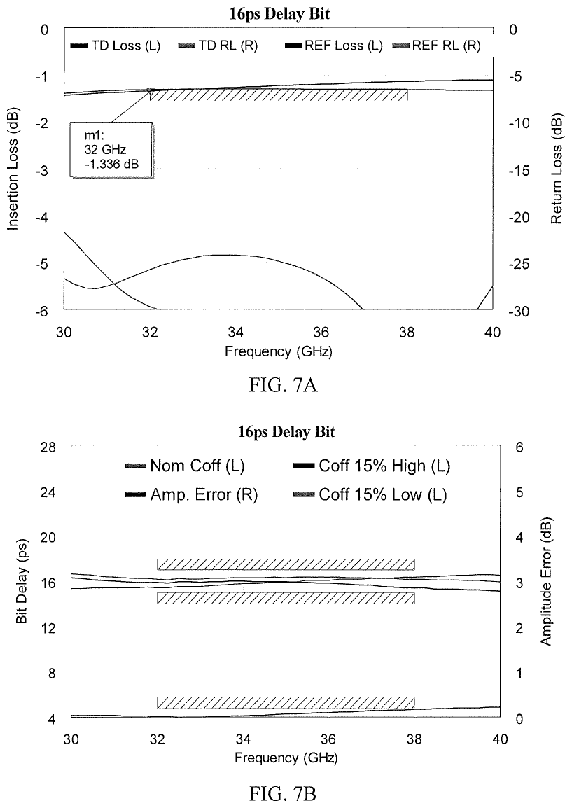

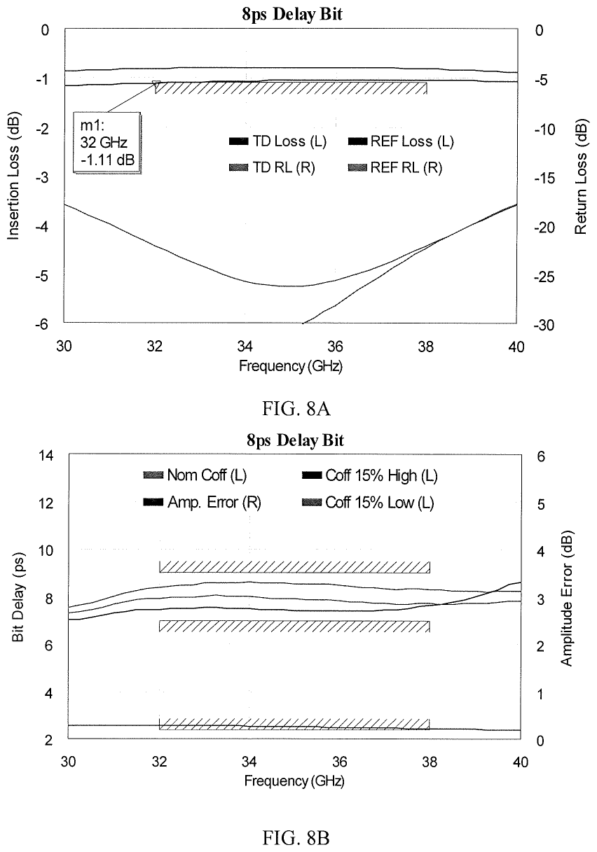

FIGS. 7A and 7B similarly illustrate the performance characteristics of the 16 ps TDU with the circuit layout 700b. FIGS. 8A and 8B similarly illustrate the performance characteristics of the 8 ps TDU with the circuit layout 700c. Overall, these plots highlight the TDUs' robust performance, with low insertion loss and minimal amplitude deviation even under variations in capacitance, showcasing the architecture's suitability for high frequency applications.

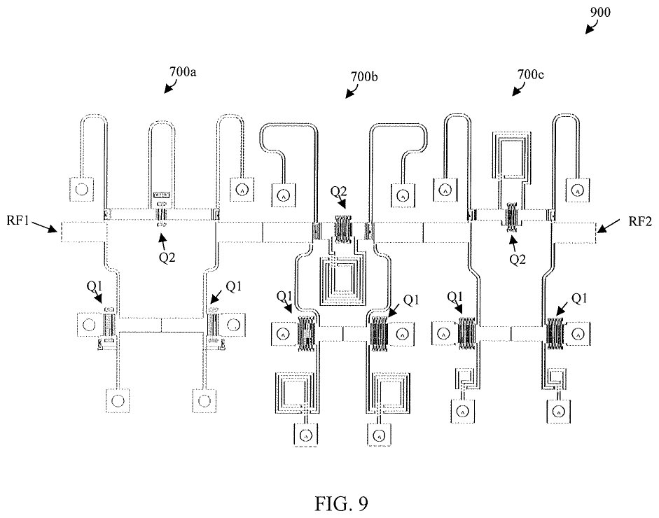

FIG. 9 illustrates a circuit layout 900 corresponding to a 3-bit TDU, which includes the circuit layouts 700a, 700c, and 700b cascaded in sequence. The reason to place the circuit layout 700c corresponding to the 8 ps TDU in the middle of the 32 ps TDU and the 16 ps TDU is mainly for achieving a better matching and less reflection. The circuit layout 900 is measured as about 2.12 mm² in area, which is about half the area of a similar 3-bit TDU but in the traditional series-shunt switch architecture.

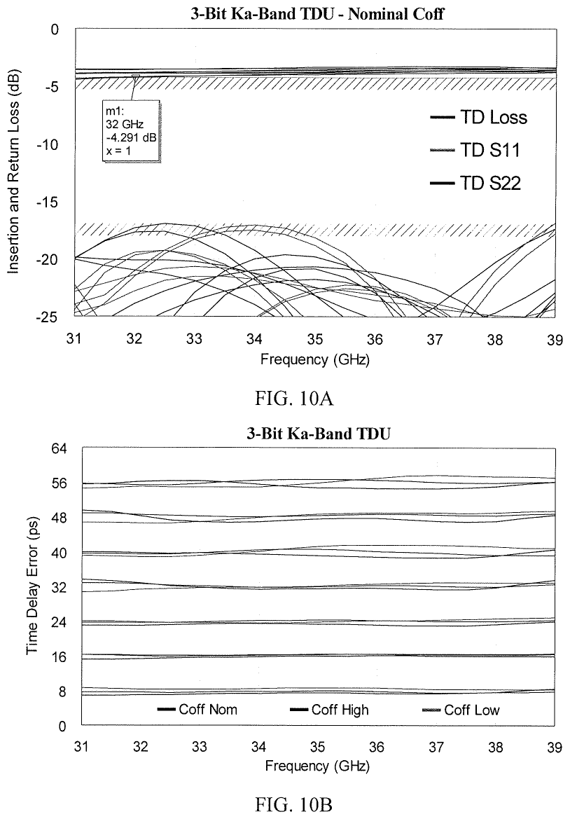

FIGS. 10A and 10B illustrate the performance characteristics of the 3-bit TDU with the circuit layout 900. The 3-bit TDU that combines a 32 ps TDU, an 8 ps TDU, and a 16 ps TDU can provide a range of selectable time delays based on the control voltage settings. In this configuration, each delay unit corresponds to a bit in the 3-bit TDU, with the 8 ps TDU serving as the least significant bit and the 32 ps TDU as the most significant bit. By selectively engaging or bypassing the delay paths in these individual TDUs, the circuit can generate a total of eight distinct time delays: Ops, 8 ps, 16 ps, 24 ps, 32 ps, 40 ps, 48 ps, and 56 ps, such as illustrated in FIG. 10B. For instance, when all delay paths are bypassed, the circuit introduces no delay (Ops). Engaging only the 8 ps TDU provides an 8 ps delay, while activating just the 16 ps TDU results in a 16 ps delay. By combining the 16 ps and 8 ps TDUs, the system achieves a 24 ps delay. Similarly, the 32 ps TDU alone offers a 32 ps delay, and when combined with the 8 ps TDU, it produces a 40 ps delay. Engaging both the 32 ps and 16 ps TDUs provides a 48 ps delay, and finally, activating all three TDUs together yields the maximum delay of 56 ps.

The exemplary multi-bit TDU not only allows for a flexible range of time delays but also ensures that the delay values remain flat across the operating frequency range. The design effectively handles capacitance variations, maintaining consistent delay performance despite fluctuations in component characteristics. Additionally, by avoiding series switches in the delay paths across the cascaded stages, the total insertion loss is minimized to approximately 4.3 dB as shown in FIG. 10A, which is significantly lower than what would typically be expected using the traditional series-shunt switch architecture. This efficiency makes the TDU particularly suitable for high-frequency applications where precision and minimal insertion loss are crucial.

It will be appreciated by those skilled in the art that the single-bit and multi-bit TDUs presented herein are merely illustrative examples. For the sake of simplicity and clarity, the descriptions focus on the essential aspects of the TDU architecture necessary to convey an understanding of the embodiments. Various embodiments may incorporate any suitable components or combinations thereof to perform tasks associated with TDUs, depending on specific requirements. Moreover, it is understood that the exemplary TDUs should not be construed to limit the types of devices in which embodiments may be implemented.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A time delay circuit, comprising:
a first port and a second port;
a reference path coupled between the first and second ports, the reference path including a series transistor and a first inductor connected in parallel with the series transistor;
a delay path coupled between the first and second ports, the delay path including a first shunt transistor, a second inductor connected in parallel with the first shunt transistor, and a first impedance inverter coupled between the first port and the first shunt transistor; and
a control circuit configured to activate one of the reference path and the delay path.

2. The time delay circuit of claim 1, wherein the delay path further includes a second shunt transistor, a third inductor connected in parallel with the second shunt transistor, and a second impedance inverter coupled between the second port and the second shunt transistor.

3. The time delay circuit of claim 2, wherein the delay path further includes a delay adjuster line coupled between the first impedance inverter and the second impedance inverter.

4. The time delay circuit of claim 1, wherein the first impedance inverter is in a form of a quarter wavelength transmission line.

5. The time delay circuit of claim 1, wherein the reference path further includes a first DC blocking capacitor coupled between the first port and the series transistor and a second DC blocking capacitor coupled between the second port and the series transistor.

6. The time delay circuit of claim 1, wherein the reference path further includes a first reference adjuster line coupled between the first port and the series transistor and a second reference adjuster line coupled between the second port and the series transistor.

7. The time delay circuit of claim 1, wherein the reference path further includes a first shunt transmission line and a second shunt transmission line, and wherein the series transistor is coupled between the first shunt transmission line and the second shunt transmission line.

8. The time delay circuit of claim 1, wherein the first inductor is in a form of a transmission line.

9. The time delay circuit of claim 1, wherein the second inductor is in a form of a transmission line.

10. The time delay circuit of claim 1, wherein the first inductor is configured to resonant with an off-state capacitance of the series transistor, and the second inductor is configured to resonant with an off-state capacitance of the first shunt transistor.

11. The time delay circuit of claim 1, wherein the reference path further includes a first capacitor connected in parallel with the series transistor, and the delay path further includes a second capacitor connected in parallel with the first shunt transistor.

12. The time delay circuit of claim 1, wherein the control circuit is configured to apply a first control voltage to a gate of the series transistor and a second control voltage to a gate of the first shunt transistor, and wherein the first control voltage and the second control voltage have a same value.

13. The time delay circuit of claim 1, wherein, in an operating band of the time delay circuit, an insertion loss of the time delay circuit at a higher frequency is less than at a lower frequency.

14. The time delay circuit of claim 1, wherein the series transistor and the first shunt transistor have different sizes.

15. A multi-bit time delay circuit, comprising:
a first stage, the first stage including a first reference path and a first delay path, wherein the first reference path includes a first series transistor and a first inductor configured to resonate with an off-state capacitance of the first series transistor, and the first delay path includes a first shunt transistor, a second inductor configured to resonate with an off-state capacitance of the first shunt transistor, and a first impedance inverter connected to the first shunt transistor; and
a second stage cascaded with the first stage, the second stage including a second reference path and a second delay path, wherein the second reference path includes a second series transistor and a third inductor configured to resonate with an off-state capacitance of the second series transistor, and the second delay path includes a second shunt transistor, a fourth inductor configured to resonate with an off-state capacitance of the second shunt transistor, and a second impedance inverter connected to the second shunt transistor.

16. The multi-bit time delay circuit of claim 15, wherein the first stage further includes a first fixed capacitor connected in parallel with the first series transistor and a second fixed capacitor connected in parallel with the first shunt transistor.

17. The multi-bit time delay circuit of claim 16, wherein the second stage is free of a fixed capacitor connected in parallel with either the second series transistor or the second shunt transistor.

18. The multi-bit time delay circuit of claim 15, further comprising:
a third stage cascaded with the second stage, the third stage including a third reference path and a third delay path, wherein the third reference path includes a third series transistor and a fifth inductor configured to resonate with an off-state capacitance of the third series transistor, and the third delay path includes a third shunt transistor, a sixth inductor configured to resonate with an off-state capacitance of the third shunt transistor, and a third impedance inverter connected to the third shunt transistor.

19. The multi-bit time delay circuit of claim 18, wherein a time delay introduced by the second stage is smaller than either of the first stage or the third stage.

20. The multi-bit time delay circuit of claim 15, wherein each of the first inductor, the second inductor, the third inductor, the fourth inductor, the first impedance inverter, and the second impedance inverter is in a form of a transmission line.
